(19) United States
(12) Patent Application Publication
(10) Pub. No.: US 2024/0028091 A1
(43) Pub. Date: Jan. 25, 2024

(54) LAPTOP COOLING SYSTEM PAD WITH COOLER

(71) Applicant: Ryan White, South Jordan, UT (US)

(72) Inventor: Ryan White, South Jordan, UT (US)

(73) Assignee: Ryan White, South Jordan, UT (US)

(21) Appl. No.: 17/871,174

(22) Filed: Jul. 22, 2022

(51) Int. Cl. G06F 1/20; H05K 7/20

(52) U.S. Cl. CPC G06F 1/203; H05K 7/20136; H05K 7/20318

(57) ABSTRACT

A laptop cooling pad having one or more heat-dissipating fans adjustable in position is disclosed with a cooler circulating cool air to the pad in question. The laptop cooling pad is provided with a ventilation portion so that a heat-dissipating fan can be mounted on the ventilation portion through a fan support. The ventilation portion has a groove for receiving coolant through the radiator so cool air can circular using fan support to move the heat-dissipating fan inside the laptop cooling pad and make the heat-dissipating fan close to a heat source, thereby ensuring the heat-dissipating effect of the laptop cooling pad. With an added function of a cooler air to be flown through specific pipes and ventilation systems. The utility model discloses a laptop cooler which comprises an upper cover plate, a bottom plate, a support, a fan, a refrigerating machine, a condenser pipe, aluminum sheets, an exhaust fan and a slide track, wherein the refrigerating machine is arranged on and attached to the bottom plate and is connected with the condenser pipe; the condenser pipe is located below the fan; the aluminum sheets parallel to a cross section of the condenser pipe are arranged outside the condenser pipe; the slide track is arranged on the upper cover plate matched with the bottom plate; the exhaust fan is arranged on the slide track; and the support is arranged below the bottom plate. The laptop cooler can blow out cold air, air movement in a laptop is accelerated, the cooling efficiency of the laptop is accelerated, and the service life of the laptop is prolonged.

### FIELD OF THE INVENTION

The present invention relates to a cooling pad and associated cooler with radiator effect by blasting coolant liquid through the device to reduce laptop heating.

### BACKGROUND OF THE INVENTION

The laptop or notebook radiator of prior art, the general simple assembling that adopts upper cover plate, base plate, support, fan forms, but due to heat in summer, the wind blowing out is hot blast, and the notebook Thermogenesis of high configuration is strong, so existing notebook radiator is limited to the heat-sinking capability of notebook, is generally merely able to reduce the temperature of 2˜5° C., this effect to notebook is very little, the serious serviceable life that has had influence on notebook.

Goal of the invention: the purpose of this utility model is that the notebook radiator that solves prior art is in the low problem of result of use in summer. Technical scheme: the technical solution of the utility model: a kind of notebook radiator, comprise upper cover plate, base plate, support, fan, refrigeration machine, condenser pipe, air exhauster, sliding rail, base plate is provided with the refrigeration machine of laminating with it, described refrigeration machine connects condenser pipe, condenser pipe is positioned at fan below, and condenser pipe is provided with that is parallel to condenser pipe cross section outward, and the upper cover plate coordinating with base plate is provided with sliding rail, sliding rail is provided with air exhauster, props up and is set up in base plate below.

Beneficial effect: the utility model compared with prior art: base plate is provided with it the refrigeration machine of laminating, both saved space, make again heating radiator there is refrigeration, and blowing cold air under the effect of fan, can make the working environment of notebook improve, and the upper cover plate coordinating with base plate is provided with sliding rail, sliding rail is provided with air exhauster, for different computer heat radiation mouth position differences, air exhauster position is set on sliding rail, facilitated everybody to change computer, and use air exhauster to coordinate with fan, accelerate the Air Flow in notebook, accelerate the radiating efficiency of notebook, extend the serviceable life of notebook.

### ACCOMPANYING DRAWING EXPLANATION

FIG. 1 is structural representation of the present utility model.

### EMBODIMENT

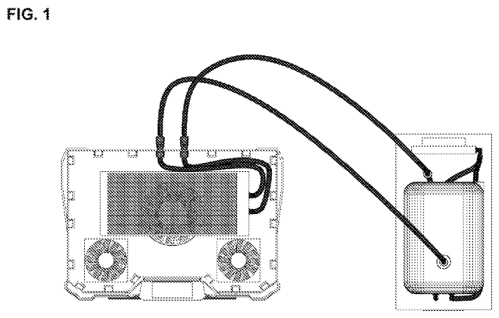

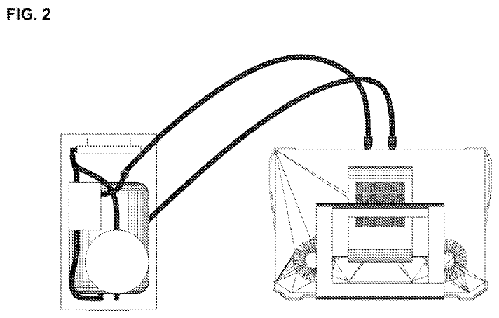

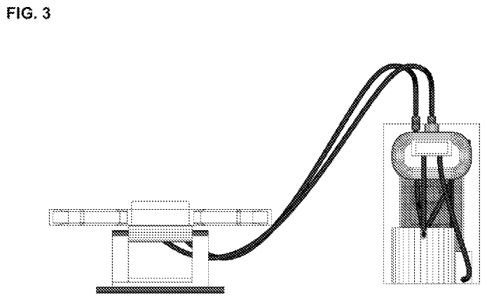

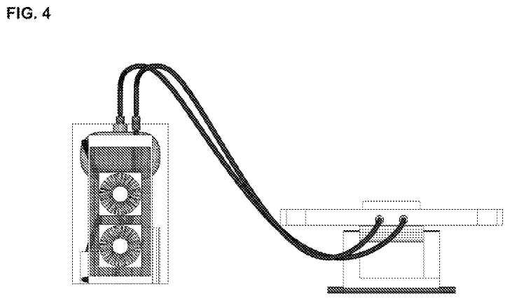

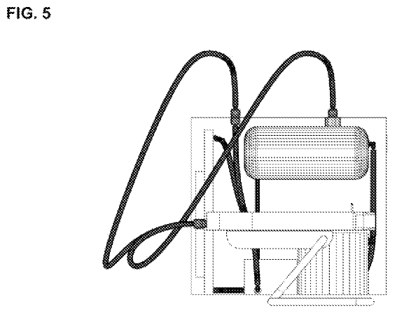

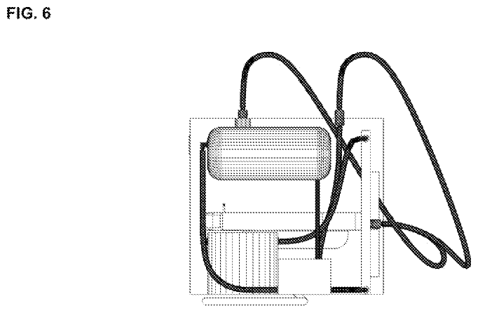

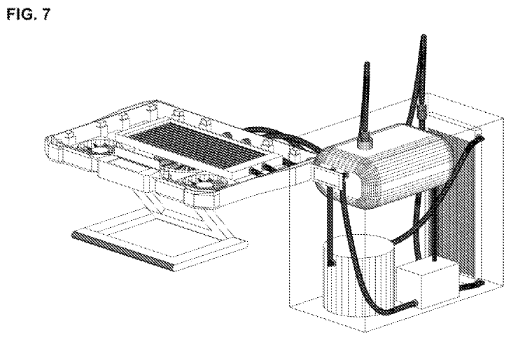

A kind of laptop cooling pad and cooler as shown in FIG. 1, comprise upper cover plate 1, base plate 2, support 3, fan 4, also comprise refrigeration machine 5, condenser pipe 6, air exhauster 7, FIG. 2 is another view of the laptop cooling pad and associated cooler, FIG. 3 is the side and standing up view of the aforementioned devices. FIGS. 4 and 5 are another view of the above, FIGS. 6 and 7 is the a close up view of the device in question.

Use the utility model, base plate is provided with the refrigeration machine of laminating with it, both saved space, make again heating radiator there is refrigeration, and blowing cold air under the effect of fan, can make the working environment of the laptop or notebook improve, and the upper cover plate coordinating with base plate is provided with sliding rail, sliding rail is provided with air exhauster, for different computer heat radiation mouth position differences, air exhauster position is set on sliding rail, facilitated everybody to change computer, and use air exhauster to coordinate with fan, accelerate the Air Flow in laptop or notebook, accelerate the radiating efficiency of laptop or notebook, extend the serviceable life of laptop or notebook.

What is claimed is:

1. A notebook radiator, comprise upper cover plate (1), base plate (2), support (3), fan (4), it is characterized in that: also comprise refrigeration machine (5), condenser pipe (6), aluminum flake (7), air exhauster (8), sliding rail (9), base plate (2) is provided with the refrigeration machine (5) of laminating with it, described refrigeration machine (5) connects condenser pipe (6), condenser pipe (6) is positioned at fan (4) below, the outer aluminum flake (7) that is parallel to condenser pipe (6) cross section that is provided with of condenser pipe (6), the upper cover plate (1) coordinating with base plate (2) is provided with sliding rail (9), sliding rail (9) is provided with air exhauster (8), support (3) is located at base plate (2) below.

2. According to the notebook radiator described in claim 1, it is characterized in that: described support (3) is jack column, be articulated with base plate (2) below.

3. According to the notebook radiator described in claim 1, it is characterized in that: described refrigeration machine (5) is connected in parallel with fan (4).
